(19) United States
(12) Patent Application Publication
(10) Pub. No.: US 2026/0162748 A1
(43) Pub. Date: Jun. 11, 2026

(54) MEMORY GENERATING PASS/FAIL INFORMATION AND OPERATING METHOD OF MEMORY

(71) Applicant: SK hynix Inc., Icheon-si (KR)

(72) Inventors: Jae KWON, Icheon-si (KR); Chae Hyoun PARK, Icheon-si (KR)

(21) Appl. No.: 19/066,766

(22) Filed: Feb. 28, 2025

(30) Foreign Application Priority Data
Dec. 5, 2024 (KR) 10-2024-0179075

(51) Int. Cl. G11C 29/44

(52) U.S. Cl. CPC G11C 29/44

(57) ABSTRACT

A memory includes a cell array including a plurality of memory cells, a pass/fail determination circuit configured to divide multi-bit data, which is read from memory cells selected by row and column addresses among the plurality of memory cells, into a plurality of groups and determine whether data is “pass” or “fail” for each group, and a section fail determination circuit configured to determine section fail information of a section, which corresponds to the row and column addresses, as “fail” when a quantity of groups determined as “fail” by the pass/fail determination circuit among the plurality of groups is greater than or equal to a first threshold value.

### CROSS-REFERENCE TO RELATED APPLICATION(S)

This application claims priority under 35 U.S.C. § 119 to Korean Patent Application No. 10-2024-0179075, filed in the Korean Intellectual Property Office on Dec. 5, 2024, the disclosure of which is incorporated herein by reference in its entirety.

### BACKGROUND

### 1. Technical Field

Various embodiments of the present disclosure relate to a memory of a semiconductor device.

### 2. Related Art

As the capacity of large memories continue to increase, the memory areas that require testing also increases rapidly in number, and the time required for testing has a significant impact on overall productivity. In addition, when defects that occur during a test processes are excessively detected and screened, an “overkill” problem may occur when too many defects are targeted, which may reduce the yield of the memory. Therefore, technology capable of appropriately filtering unnecessary errors in test results is required and such filtering may improve the yield of the memory and prevent the overkill problem.

### SUMMARY

In accordance with an embodiment of the present disclosure, a memory may include: a cell array including a plurality of memory cells and providing read data from the plurality of memory cells selected by row and column addresses; a pass/fail determination circuit configured to divide the read data into a plurality of multi-bit data groups and to determine whether each multi-bit data group is “pass” or “fail”; and a section fail determination circuit configured to determine section fail information of sections, which correspond to the received row and column addresses and each section associated with one of the plurality of multi-bit data groups, as “fail” when the number of the plurality of multi-bit data groups determined as “fail” by the pass/fail determination circuit is greater than or equal to a first threshold value.

In accordance with an embodiment of the present disclosure, an operating method of a memory may include: reading data of memory cells selected by a row address and a column address; dividing the data read from the memory cells into a plurality of groups; determining whether data is “pass” or “fail” for each group; and generating section fail information of a section, which corresponds to the row and column addresses, as “fail” when a number of groups from the plurality of groups determined as “fail” by a pass/fail determination circuit is greater than or equal to a first threshold value.

### BRIEF DESCRIPTION OF THE DRAWINGS

FIG. 1 is a block diagram illustrating a memory in accordance with an embodiment of the present disclosure.

FIG. 2 is a block diagram illustrating an example of a test circuit of FIG. 1 in accordance with an embodiment of the present disclosure.

FIG. 3 is a block diagram illustrating an example of a pass/fail determination circuit and a section fail determination circuit of FIG. 2 in accordance with an embodiment of the present disclosure.

FIGS. 4 to 7 are diagrams illustrating an operation of a filtering circuit of FIG. 2 in accordance with an embodiment of the present disclosure.

### DETAILED DESCRIPTION

Various embodiments of the present disclosure are directed to technology for filtering and outputting pass/fail information pertaining to a memory.

According to embodiments of the present disclosure, it is possible to filter and output pass/fail information of a memory and reduce unnecessary errors in test results.

Hereinafter, various embodiments according to the technical spirit of the present disclosure are described below with reference to the accompanying drawings.

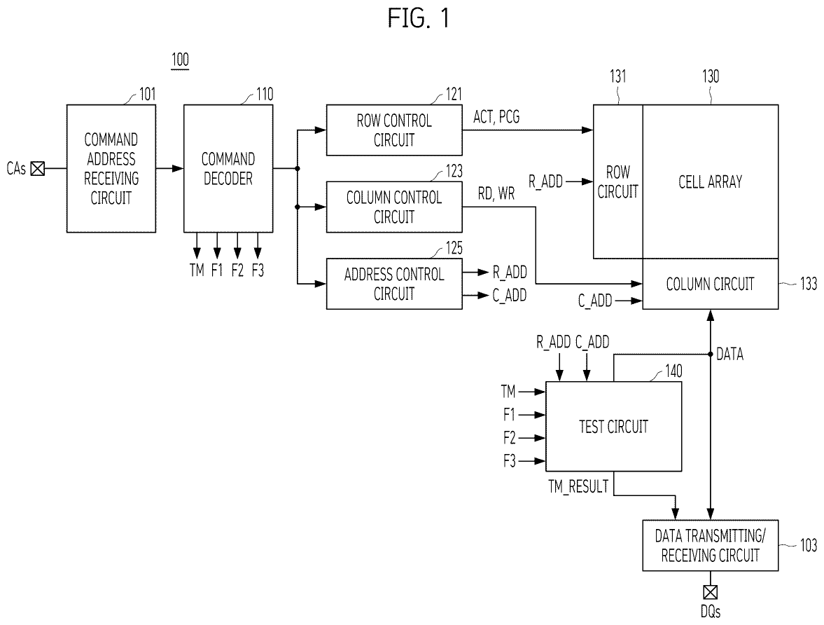

FIG. 1 is a block diagram illustrating a memory in accordance with an embodiment of the present disclosure.

Referring to FIG. 1, a memory 100 includes a command address receiving circuit 101, a data transmitting/receiving circuit 103, a command decoder 110, a row control circuit 121, a column control circuit 123, an address control circuit 125, a cell array 130, a row circuit 131, a column circuit 133, and a test circuit 140.

The command address receiving circuit 101 receives a command and an address, which are inputted to a plurality of command address terminals CAs. Depending on specifications of the memory 100, the command and address may be inputted to the same input terminals or separate input terminals. Herein, it is described as an example that the command and address are inputted to the same input terminals CAs.

The data transmitting/receiving (input/output) circuit 103 receives data transmitted to a plurality of data terminals DQs or transmits data to the plurality of data terminals DQs. The data transmitting/receiving circuit 103 receives data DATA to be written to the cell array 130 during a write operation, and transmits data DATA read from the cell array 130 during a read operation.

The command decoder 110 decodes the command and address to identify the type of operation instructed to the memory 100. In addition, the command decoder 110 may activate a test mode signal TM when the setting of a test mode is instructed. Moreover, the command decoder 110 may generate signals F1, F2 and F3 indicating a filtering mode of the test circuit 140 during the test mode.

When the decoding result of the command decoder 110 indicates that a row operation such as an active operation and a pre-charge operation is instructed, the row control circuit 121 controls the row operation. An active signal ACT is a signal indicating the active operation, and a pre-charge signal PCG is a signal indicating the pre-charge operation.

When the decoding result of the command decoder 110 indicates that a column operation such as a write operation and a read operation is instructed, the column control circuit 123 controls the column operation. A write signal WR is a signal indicating a write operation, and a read signal RD is a signal indicating a read operation.

The address control circuit 125 classifies the address received from the command decoder 110 into a row address R_ADD and a column address C_ADD and transmits the row address R_ADD and the column address C_ADD to the row circuit 131 and the column circuit 133, respectively. The address control circuit 125 may classify the received address into the row address R_ADD when the decoding result of the command decoder 110 indicates that an active operation is instructed, and classify the received address into a column address C_ADD when the decoding result of the command decoder 110 indicates that read and write operations are instructed.

The cell array 130 includes memory cells arranged in a plurality of rows and a plurality of columns. The row circuit 131 controls the rows of the cell array 130. When an active signal ACT is activated, the row circuit 131 activates a row selected by the row address R_ADD from among the rows of the cell array 130. During the active operation, data in memory cells of the selected row may be detected and amplified. In addition, the row circuit 131 may pre-charge the activated row when the pre-charge signal PCG is activated.

During a write operation, the column circuit 133 writes data DATA to columns, from among the columns of the cell array 130, selected by the column address C_ADD. That is the column circuit 133 writes data to memory cells corresponding to the activated row and the selected columns. In addition, during a read operation, the column circuit 133 reads data DATA from the columns, from among the columns of the cell array 130, selected by the column address C_ADD. That is the column circuit 133 reads data from the memory cells corresponding to the activated row and the selected columns.

The test circuit 140 is activated and operates in the test mode when test mode signal TM is activated. In test mode, the test circuit 140 may generate a test result TM_RESULT using the data DATA read by the column circuit 133. The test result TM_RESULT generated by the test circuit 140 may be outputted through the data transmitting/receiving circuit 103. That is, in test mode, the data transmitting/receiving circuit 103 may output the test result TM_RESULT instead of the data DATA.

The test circuit 140 generates the test result TM_RESULT using the data DATA read from the cell array 130. Before the test result is generated by the test circuit 140, the same data may be written to all the memory cells of the cell array 130. That is, “1” may be stored in all the memory cells of the cell array 130, or “0” may be stored in all the memory cells of the cell array 130.

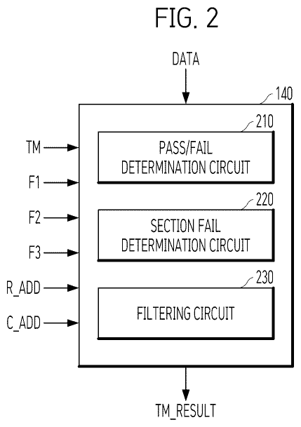

FIG. 2 is a block diagram illustrating an example of a test circuit of FIG. 1 in accordance with an embodiment of the present disclosure.

Referring to FIG. 2, a test circuit 140 includes a pass/fail determination circuit 210, a section fail determination circuit 220, and a filtering circuit 230.

The pass/fail determination circuit 210 divides data DATA read from a memory cell array into a plurality of groups and determines whether the data DATA are “pass” or “fail” for each group. For example, 64-bit data DATA may be divided into 8 groups, each group having 8-bit data, and each group is determined as “pass” or “fail”.

The section fail determination circuit 220 determines section fail information of a section, which corresponds to the row address R_ADD and column address C_ADD of memory cells on which the read operation is performed, as “fail” when a number of groups determined as “fail” by the pass/fail determination circuit 210 among the groups of the section meets or exceeds a predetermined number, for example, 3 or more.

The filtering circuit 230 filters the section fail information generated by the section fail determination circuit 220 when the filtering mode is set and when one of the filtering mode signals F1, F2 and F3 is activated. When all of the filtering mode signals F1, F2 and F3 are deactivated, the filtering circuit 230 may be deactivated, and unfiltered section fail information may be generated as the test result TM_RESULT.

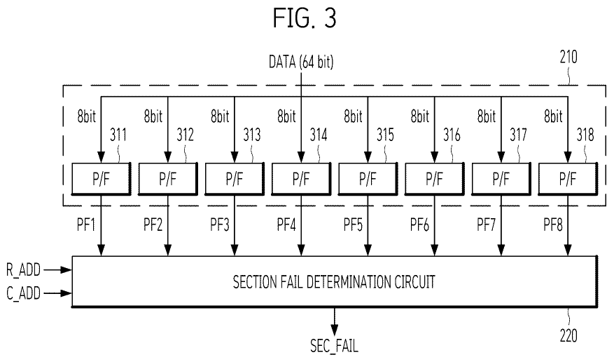

FIG. 3 is a block diagram illustrating an example of a pass/fail determination circuit and a section fail determination circuit of FIG. 2 in accordance with an embodiment of the present disclosure.

Referring to FIG. 3, a pass/fail determination circuit 210 includes pass/fail determination units 311 to 318. From a read operation, 64-bit data DATA is divided into 8 groups each having 8-bit data, and each 8-bit data is inputted to different pass/fail determination units 311 to 318, respectively. When all 8-bit data inputted to the pass/fail determination units 311 to 318 have the same value, each of the pass/fail determination units 311 to 318 may determine the corresponding 8-bit data input as “pass”. When at least one bit among the 8-bit data has a different value, each of the pass/fail determination units 311 to 318 may determine the 8-bit data input as “fail”. That is, the pass/fail determination units 311 to 318 may perform an XOR operation and generate pass/fail signals PF1 to PF8, respectively. The pass/fail signals PF1 to PF8, which are signals indicating pass or fail of the groups of 8-bit data, may have a value of “0” when the data is determined as “pass” and have a value of “1” when the data is determined as “fail”. Although in FIG. 3, the read data DATA has 64 bits and the 64-bit data DATA is divided into 8 groups, this is merely an example, and it is obvious that the quantity of bits of the data DATA and the number of groups may vary in other embodiments.

The section fail determination circuit 220 determines section fail information SEC_FAIL of a section, which corresponds to a row address R_ADD and a column address C_ADD from among the row addresses and column addresses of the read data. For example in FIG. 3, when a quantity of signals determined as “fail” among the pass/fail signals PF1 to PF8 for a plurality of groups is greater than or equal to a threshold value, such for example 3, the section fail information of the corresponding row and column addresses for that plurality of groups are set to “fail”. The section fail information SEC_FAIL may have a format such as [a value of a row address/a value of a column address/fail status]. The value of the row address and the value of the column address may represent values of row address and column address corresponding to the data DATA, and fail status may have a value of “0” when a corresponding section is determined as “pass” and may have a value of “1” when the corresponding section is determined as “fail”.

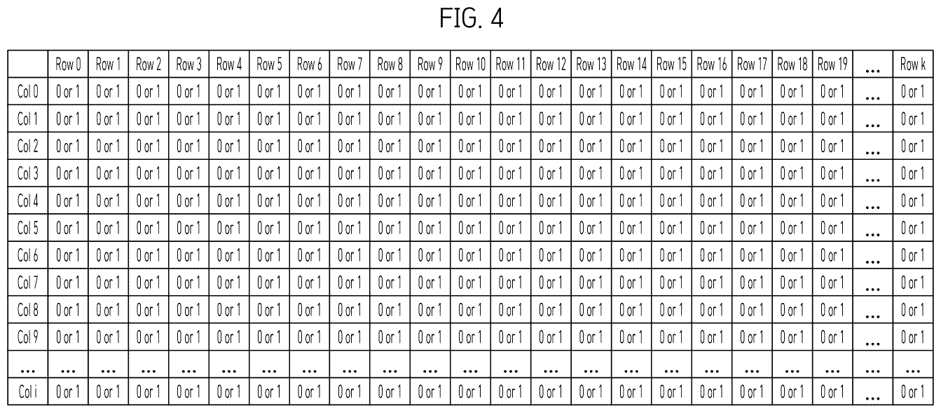

FIGS. 4 to 7 are diagrams illustrating an operation of a filtering circuit of FIG. 2 in accordance with an embodiment of the present disclosure.

FIG. 4 is a table that illustrates a plurality of pieces of section fail information SEC_FAIL generated by a section fail determination circuit 220. In the table, (k+1)*(i+1) section fail information SEC_FAIL are listed, starting from the intersection of a section fail information of a zeroth row where a value of a row address is 0 and a zeroth column where a value of a column address is 0, and ending at the section fail information of a k^{th} row and an i^{th} column. A value of “0 or 1” indicates that the section fail information SEC_FAIL has a value of “0” when a section corresponding to the row and column address is “pass” and has a value of “1” when the section corresponding to the row and column address is “fail”. Because it is possible that a single piece of section fail information is generated during one read operation, the section fail information shown in FIG. 4 may be results of a (k+1)*(i+1) number of read operations performed as the row address R_ADD and the column address C_ADD are changed or incremented.

In FIG. 4, no filtering is performed on the section fail information shown. When the filtering circuit 230 does not perform a filtering operation, that is, when all of the filtering mode signals F1, F2 and F3 are deactivated, a test result TM_RESULT may be generated as illustrated in FIG. 4.

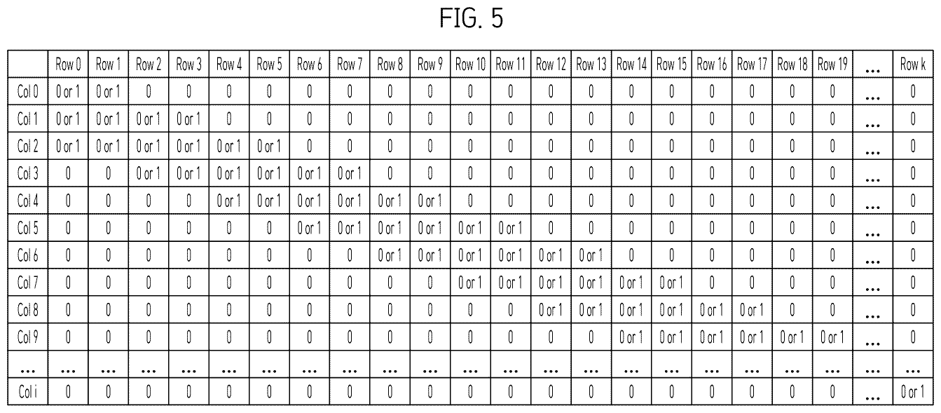

FIG. 5 is a diagram illustrating a test result TM_RESULT filtered and generated by the filtering circuit 230 when a first filtering mode is set, that is, when the filtering mode signal F1 is activated. The first filtering mode is a filtering mode in which section fail information corresponding to predetermined address values of target row addresses and column addresses maintain as they are while the section fail information for the remaining row addresses and column addresses are processed as “pass”. For example in FIG. 5, the filtering mode signal F1 corresponds to preset values of target row addresses and column addresses located in a diagonal portion of the cell array 130. Referring to FIG. 5, it may be seen that the section fail information located at target row addresses and column addresses in the diagonal portion keep their original values of “0 or 1”, but the section fail information for the remaining row addresses and column addresses have a value of “0”. As a result, the section fail information for the remaining row addresses and column addresses that are not predetermined according to the filtering mode signal F1 are processed as “pass” and the section fail information is set at “0”. Therefore, the first filtering mode may be used when only pass/fail information of areas of interest or areas desired to be analyzed are selected and monitored or analyzed.

In the first filtering mode, a test result TM_RESULT filtered as shown in FIG. 5 may be generated and outputted. In FIG. 5, a unfiltered area is an area located in the diagonal portion of the cell array 130, but it is obvious in other embodiments that the non-filtered areas may be in other areas and may be arranged differently.

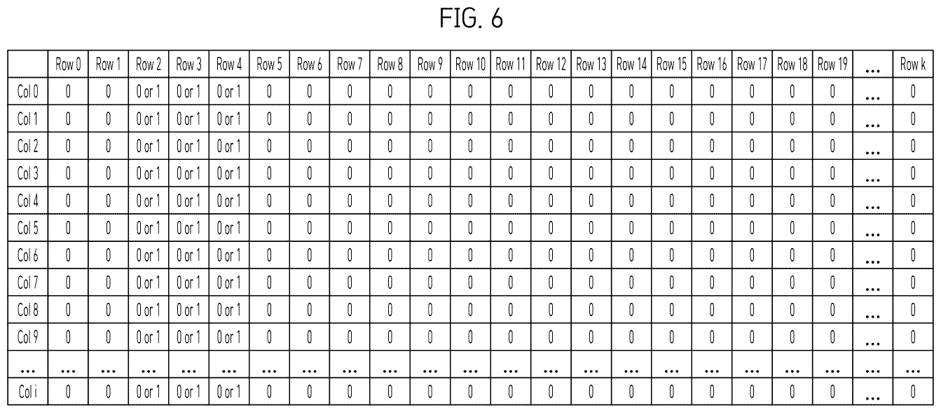

FIG. 6 is a diagram illustrating a test result TM_RESULT filtered and generated by the filtering circuit 230 when a second filtering mode is set, that is, when the filtering mode signal F2 is activated. The second filtering mode is a filtering mode in which, when a quantity of sections in which section fail information is “fail” in an N number of adjacent rows is greater than or equal to a threshold value (e.g., greater than or equal to 3 rows in FIG. 6), section fail information of the adjacent N rows maintain as they are while the section fail information for the other rows are processed as “pass”. Referring to FIG. 6, only section fail information of second, third and fourth rows maintain their original values of “0 or 1”, and the section fail information in all other rows have a value of “0”, that is, the other section fail information outside of the adjacent N number of target rows are processed as “pass”. Because a quantity of failed sections in three consecutive rows, that is, the second, third and fourth rows, is greater than or equal to the threshold value, the section fail information of the second, third and fourth rows maintain their original values, and the other rows are processed as “pass” because there are no rows that satisfy the condition corresponding to the filtering mode signal F2. In this example, the second filtering mode may be used when only pass/fail information are selected and monitored or analyzed where fails occur excessively in consecutive rows.

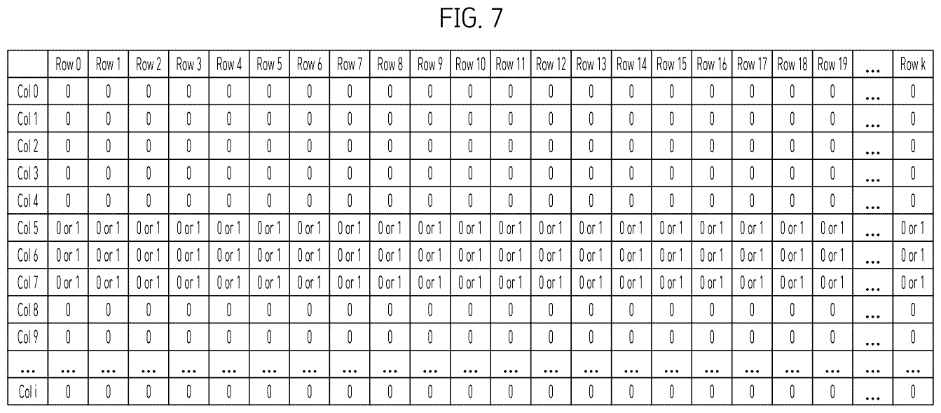

FIG. 7 is a diagram illustrating a test result TM_RESULT filtered and generated by the filtering circuit 230 when a third filtering mode is set, that is, when the filtering mode signal F3 is activated. The third filtering mode is a filtering mode in which, when a quantity of sections in which section fail information is “fail” in an M number of adjacent columns is greater than or equal to a threshold value (e.g., greater than or equal to 3 columns in FIG. 7), section fail information of the adjacent M columns maintain as they are while the section fail information for the other columns are processed as “pass”. Referring to FIG. 7, only section fail information of fifth, sixth and seventh columns maintain their original values of “0 or 1”, and the section fail information in all columns have a value of “0”, that is, the other section fail information outside of the adjacent M number of columns are processed as “pass”. Because a quantity of failed sections in three consecutive columns, that is, the fifth, sixth and seventh columns, is greater than or equal to the threshold value, the section fail information of the fifth, sixth and seventh columns maintain their original values, and the other rows are processed as “pass” because there are no columns that satisfy the condition corresponding to the filtering mode signal F3. In this example, the third filtering mode may be used when only pass/fail information are selected and monitored or analyzed where fails occur excessively in consecutive columns.

Although the technical spirit of the present disclosure has been described above according to embodiments, this is only for explaining the embodiments according to the concepts of the present disclosure, and the present disclosure is not limited to the above embodiments. Various embodiments may be applied by those skilled in the art, to which the present disclosure pertains, within the scope of the technical spirit of the present disclosure.

What is claimed is:

1. A memory comprising:
a cell array including a plurality of memory cells and providing read data from the plurality of memory cells selected by row and column addresses;
a pass/fail determination circuit configured to divide the read data into a plurality of multi-bit data groups and to determine whether each multi-bit data group is “pass” or “fail”; and
a section fail determination circuit configured to determine section fail information of sections, which correspond to the row and column addresses and each section associated with one of the plurality of multi-bit data groups, as “fail” when the number of the plurality of multi-bit data groups determined as “fail” by the pass/fail determination circuit is greater than or equal to a first threshold value.

2. The memory of claim 1, wherein a read operation is performed multiple times changing one or more values of the row and column addresses, and a fail determination operation of the pass/fail determination circuit and the section fail determination circuit is performed whenever the read operation is performed.

3. The memory of claim 2, further comprising:
a filtering circuit configured to filter the section fail information generated for each of the row and column addresses; and
an output circuit configured to output a filtering result of the filtering circuit.

4. The memory of claim 3, wherein when a filtering mode is set, the filtering circuit maintains section fail information corresponding to predetermined target row and column addresses as they are and processes remaining section fail information as “pass”.

5. The memory of claim 4, wherein the predetermined target row and column addresses have values of row and column addresses located in a diagonal portion of the cell array.

6. The memory of claim 3, wherein when a filtering mode is set and the number of sections in which the section fail information is “fail” in an N number of adjacent rows is greater than or equal to a threshold value (where “N” is an integer greater than or equal to 2), the filtering circuit maintains section fail information of sections in the N number of adjacent rows as they are and assigns a “pass” value to sections of remaining rows.

7. The memory of claim 3, wherein when a filtering mode is set and the number of sections in which section fail information is “fail” in an M number of adjacent columns is greater than or equal to a third threshold value (where “M” is an integer greater than or equal to 2), the filtering circuit maintains section fail information of sections in the M number of columns as they are and processes section fail information in sections in the remaining columns as “pass”.

8. The memory of claim 1, wherein the pass/fail determination circuit performs an XOR operation for each group and determines “pass” or “fail”.

9. An operating method of a memory, the operating method comprising:
reading data of memory cells selected by a row address and a column address;
dividing the data read from the memory cells into a plurality of groups;
determining whether data is “pass” or “fail” for each group; and
generating section fail information of a section, which corresponds to the row and column addresses, as “fail” when a number of groups from the plurality of groups determined as “fail” by a pass/fail determination circuit is greater than or equal to a first threshold value.

10. The operating method of claim 9, wherein the reading of the data of the memory cells, the dividing of the data, the determining of whether the data is “pass” or “fail” and the generating of the section fail information are performed multiple times by changing one or more of the row address and the column address.

11. The operating method of claim 10, further comprising:
filtering section fail information generated for each value of the row and column addresses; and
outputting the filtered section fail information.

12. The operating method of claim 11, wherein the filtering of the section fail information includes maintaining section fail information corresponding to predetermined values of the row and column addresses as they are and processing the other section fail information as “pass” in response to setting of a filtering mode.

13. The operating method of claim 12, wherein the predetermined values of the row and column addresses are values of row and column addresses of sections located in a diagonal portion of a cell array.

14. The operating method of claim 11, wherein the filtering of the section fail information includes:
selecting rows, in which a quantity of sections where the section fail information is “fail” is greater than or equal to a second threshold value, from adjacent N rows (where “N” is an integer greater than or equal to 2) in response to setting of a filtering mode; and
maintaining the section fail information of the selected adjacent N rows as they are and processing the other section fail information as “pass”.

15. The operating method of claim 11, wherein the filtering of the section fail information includes:
selecting columns, in which a quantity of sections where the section fail information is “fail” is greater than or equal to a third threshold value, from adjacent M columns (where “M” is an integer greater than or equal to 2) in response to setting of a filtering mode; and
maintaining the section fail information of the selected adjacent M columns as they are and determining the other section fail information as “pass”.

16. The operating method of claim 9, wherein the determining of whether the data is “pass” or “fail” includes performing an XOR operation for each group.
